(19) United States
(12) Patent Application Publication
(10) Pub. No.: US 2023/0242812 A1
(43) Pub. Date: Aug. 3, 2023

(54) METHOD FOR DEPOSITING AN INORGANIC PEROVSKITE LAYER

(71) Applicant: COMMISSRIAT À L'ÉNERGIE ATOMIQUE ET AUX ÉNERGIES AL TERNATIVES, Paris (FR)

(72) Inventors: Louis Grenet, Grenoble (FR); Fabrice Emieux, Grenoble (FR); Jean-Marie Verilhac, Grenoble (FR)

(21) Appl. No.: 18/003,023

(22) PCT Filed: Jun. 22, 2021
(86) PCT No.: PCT/FR2021/051130

§ 371 Date: Dec. 22, 2022

(30) Foreign Application Priority Data
Jun. 30, 2020 (FR) 2006842

(51) Int. Cl. C09K 11/66; C01G 21/16; C30B 23/06; C30B 29/12; C23C 14/06; C23C 14/24

(52) U.S. Cl. CPC C09K 11/665; C01G 21/16; C30B 23/06; C30B 29/12; C23C 14/0694; C23C 14/24; C01P 2002/34; C01P 2002/72; G01T 1/2023

(57) ABSTRACT

A method for depositing an inorganic perovskite layer, comprising the following steps: providing a substrate and an inorganic target; positioning the substrate and the target in a close-space sublimation furnace; depositing an inorganic perovskite layer onto the substrate by sublimation of the target.

### TECHNICAL FIELD

The present invention relates to the general field of methods for depositing inorganic perovskite layers.

The invention finds applications in many industrial fields, in particular in the field of X-ray detection for medical applications, but also in the field of photovoltaics, gamma radiation detection, or else for the manufacture of electronic, optical or optoelectronic devices, in particular for the manufacture of light-emitting diodes (LED), photo-detectors, scintillators or transistors.

The invention is particularly interesting since it allows depositing thick inorganic perovskite layers (typically larger than or equal to 0.1 mm or else larger than 1 mm).

### Prior Art

Currently, ABX₃ type perovskites (PVK) can be obtained by different methods.

A first method consists in making CsPbBr₃ crystals grow using solution growth methods. In this case, the precursors CsBr and PbBr₂ are dissolved in one or more solvent(s) and the system is subjected to a temperature variation which leads to supersaturation of the precursors in solution and initiates the growth of crystals [1].

Single crystals having a perovskite structure of formula MAPbI₃, FAPbI₃, and MAPbBr₃ (with MA methylammonium and FA formamidinium) have also been synthesised from a liquid solution [2].

However, these growth methods in solution are difficult to transpose to obtain homogeneous deposits over large surfaces.

Another method consists in synthesising perovskite materials by hot pressing. For this purpose, a CsPbBr₃ powder is placed over a 2.5 cm×2.5 cm FTO substrate and then the whole is heated up to 873K until the powder melts. Afterwards, a quartz plate is placed over the molten material. On cooling, the material solidifies. Thus, almost single crystalline films of CsPbBr₃ about a hundred micrometres thick have been obtained [3]. However, such a process requires strong heating of the substrate, which is incompatible with use on TFT (“Thin Film Transistor”) type detector arrays.

Hybrid organic/inorganic perovskites of formula AMX₃ have also been obtained by close-space sublimation (or CSS standing for “Close Space Sublimation”) [4]. For this purpose, it is first necessary to deposit, over a substrate, a layer of precursor MX₂ with X with a halide ion and M a cation of a divalent metal, and provide a source A of organic material (for example CH₃NH₃⁺). The precursor layer has a thickness, for example, from 30 nm to 500 nm. The source has, for example, a thickness of 1 mm. Then the precursor layer and the source are heated. Only the organic portion is sublimated. A substrate covered with an organic/inorganic hybrid perovskite is thus obtained. However, with such a process, it is not possible to form thick perovskite layers.

### DISCLOSURE OF THE INVENTION

An object of the present invention is to provide a method for depositing an inorganic perovskite layer over a substrate, the method being simple to implement, allowing forming layers of variable thickness (typically from a few hundred nanometres to thicknesses larger than or equal to 0.5 mm), homogeneous both across the thickness and over the surface, over large surfaces, in a reasonable time (less than one day and preferably less than 6 h). This method is particularly interesting for the deposition of thick layers (typically thicknesses larger than or equal to 0.1 mm) to be implemented at moderate temperatures (typically lower than 350° C.).

For this purpose, the present invention provides a method for depositing an inorganic perovskite layer comprising the following steps:

a) providing a substrate and an inorganic target,

b) positioning the substrate and the target, in a close-space sublimation furnace,

c) depositing an inorganic perovskite layer onto the substrate by sublimation of the target.

The invention differs from the prior art essentially by the deposition of an inorganic perovskite layer material by close-spaced sublimation (CSS). The material of the target having the composition of the perovskite that one seeks to obtain, there is no need to form a layer of precursor over the substrate beforehand.

Depending on the deposition time and/or the thickness of the target, it is possible to obtain layers with large thicknesses (typically larger than or equal to 0.1 mm, for example from 0.1 mm to 3 mm), with small thicknesses (typically smaller than 2 μm), or with intermediate or medium thicknesses (typically from 2 μm to less than 0.1 mm).

Thus, the obtained perovskite layers have a uniform thickness and homogeneous characteristics over the entire deposition surface. The process is repeatable and can be used to deposit perovskite layers over surfaces of various dimensions, for example from 1 cm² to 1 m².

According to a first advantageous variant, the inorganic perovskite layer has the formula A′₂C¹⁺D³⁺X₆, A₂B⁴⁺X₆ or A₃B₂³⁺X₉ with A, A′ and X possibly being ions or a mixture of ions complying with electron neutrality. A, A′, C, D, B are cations and X an anion.

According to a second advantageous variant, the inorganic perovskite layer has the formula A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ with A and B cations and X anions.

According to a third advantageous variant, the inorganic perovskite layer has the formula ABX₃ with A and B cations and X an anion. Preferably, the inorganic perovskite layer is made of CsPbBr₃. Even more preferably, the inorganic perovskite layer is made of CsPbBr₃ and it has a thickness larger than or equal to 100 μm. Such a layer is particularly advantageous for X-ray detection applications in the medical field.

According to a particular embodiment, the target is a solid target formed of an inorganic perovskite film. Such a film is deposited, for example, over a glass substrate. With such a target, it is possible to manufacture perovskite layers with a small, medium or large thickness. This variant is particularly advantageous for forming thin perovskite layers because the target can be used for several successive depositions.

According to another particular embodiment, the target is formed of particles.

According to a variant of this particular embodiment, the target comprises particles of formula ABX₃.

According to another variant of this particular embodiment, the target comprises particles of formula AX, particles of formula BX₂ and, possibly, particles of formula ABX₃.

According to an advantageous embodiment, the target is a solid target, formed of agglomerated particles. This variant allows manufacturing perovskite layers with small, medium or large thickness. This variant is particularly advantageous for forming very thick perovskite layers.

According to another advantageous embodiment, the particles form a bed of powder. This variant is particularly advantageous for forming perovskite layers with small or medium thickness.

Advantageously, the target provided in step a) is obtained according to the following steps:
mechanosynthesis by co-grinding of a first material of formula AX and a second material of formula BX₂ so as to obtain a powder of formula ABX₃,
pressing the powder of formula ABX₃ to obtain a solid target of formula ABX₃.

Advantageously, before step c), the method comprises an additional step during which the target is heated up to temperatures ranging from 100° C. to 500° C. and is subjected to a pressure higher than 10³ Pa. During this step, the target is not sublimated. This high pressure leads to an interdiffusion of the elements in presence, and thus to the formation of particles of formula ABX₃ and/or to the agglomeration of the particles of the target. Thus, when the target is formed of particles of formula AX and particles of formula BX₂, it is possible to form the ABX₃ phase in situ and therefore to sublimate during step c) only the right crystallographic phase. This step is carried out under a neutral atmosphere, for example under argon or under nitrogen. Such a step is advantageously carried out in the close-space sublimation furnace, between step b) and step c).

Advantageously, during step c), the temperature difference between the target and the substrate will range from 50° C. to 350° C. and preferably from 50° C. to 200° C.

According to a particular variant, step c) is carried out at a pressure P lower than 1 Pa, and preferably lower than 0.1 Pa.

According to another particular variant, step c) is carried out under a reducing atmosphere or under an oxidising atmosphere.

Preferably, to form thick layers, a substrate will be selected whose coefficient of thermal expansion is close to that of the inorganic perovskite layer to be deposited. By close, it should be understood that their coefficients of thermal expansion do not vary by more than 25%, and preferably, they do not vary by more than 10%. Advantageously, the substrate is a TFT (“Thin Film Transistor”) array deposited over a support, for example made of glass, silicon or polyimide.

Advantageously, before step c), the method comprises an additional step during which an intermediate layer, whose nature is identical to or different from the inorganic perovskite layer, is deposited over the substrate in order to improve the quality of the main layer and/or the operation of the final device. The intermediate layer can:
serve as a bonding layer, and/or
assist in crystallisation by promoting homoepitaxy or heteroepitaxy of the inorganic perovskite layer, and/or
ensure good electrical contact between the substrate and the inorganic perovskite layer, and/or
have optoelectronic properties, and/or
serve as a buffer layer in order to compensate for the difference in the coefficient of thermal expansion between the main layer and the substrate.

The method has at least one or more of the following advantages:
obtaining a target directly having the right crystallographic phase,
forming inorganic perovskite layers with large thickness (larger than or equal to 100 μm and preferably larger than 300 μm),
forming homogeneous layers across the thickness and over the surface,
form inorganic perovskite layers over large surfaces (more than a few tens of cm²),
the process is carried out over reasonable times (preferably less than 5 h and preferably less than 2 h), since the deposition rate is advantageously higher than 100 μm/h and preferably higher than 500 μm/h,
the method is implemented at moderate substrate temperatures (lower than 350° C., preferably lower than 300° C. and even more preferably lower 250° C.), which allows using a wide range of substrates and/or media (TFT array, silicon, glass, polymer . . . ),
CSS deposition allows for a high material utilisation rate (up to 90% of sublimated material is deposited) compared to other vacuum deposition methods for which only 30% of the material is deposited, thus reducing manufacturing costs,
the process is repeatable and applicable on a large scale,
the obtained inorganic perovskite layers have good purity (the CSS deposit is purer than the target, the impurities generally not being sublimated).

The invention also relates to a stack comprising a substrate and an inorganic perovskite layer obtained by a method as described before, the inorganic perovskite layer being made of CsPbBr₃ and having a thickness larger than or equal to 100 μm.

The invention also relates to the use of a stack as defined before for X-ray detection applications, in particular in the medical field. For example, we will use:
a CsPbBr₃ layer with a thickness comprised between 100 and 400 μm for X-ray mammography (absorption between 97 and 100%),
a CsPbBr₃ layer with a thickness larger than 0.65 mm for X-ray radiography (RQA5 range 30 to 70 keV) to have >90% absorption,
a CsPbBr₃ layer with a thickness larger than 1.4 mm for X-ray radiography (RQA9 range from 40 to 120 keV) to have >90% absorption.

Other features and advantages of the invention will arise from the complementary description that follows.

It goes without saying that this complementary description is given only for illustration of the object of the invention and should in no way be interpreted as a limitation of this object.

### BRIEF DESCRIPTION OF THE DRAWINGS

The present invention will be better understood upon reading the description of embodiments given merely for indicative and non-limiting purposes with reference to the appended drawings wherein:

FIG. 1 represents, schematically in section, an inorganic perovskite layer deposited over a substrate according to a particular embodiment of the invention.

FIG. 2 represents, schematically in section, a stack comprising a support, a substrate and an inorganic perovskite layer according to a particular embodiment of the invention.

FIG. 3 represents, schematically in section, a stack comprising a support, a substrate, an intermediate layer and an inorganic perovskite layer according to a particular embodiment of the invention.

FIG. 4 represents, schematically, and in section, a CSS furnace according to a particular embodiment of the invention.

FIG. 5 represents, schematically, and in section, a susceptor and a cover of a CSS furnace according to a particular embodiment of the invention.

FIG. 6 represents X-ray diffractograms of a PbBr₂ powder, of a CsBr powder, and of a CsPbBr₃ powder obtained by co-grinding, according to a particular embodiment of the invention, as well as the expected peaks for a CsPbBr₃ powder (PDF map 00-054-0752, bar chart).

FIG. 7 is a photograph representing a deposit over a glass substrate made from a CsPbBr₃ target, according to a particular embodiment of the invention.

The different portions represented in the figures are not necessarily plotted according to a uniform scale, to make the figures more readable.

### DETAILED DISCLOSURE OF PARTICULAR EMBODIMENTS

Although this is in no way limiting, the invention is particularly interesting for the manufacture of electronic, optical or optoelectronic devices based on inorganic perovskite (or for example, it might be LEDs, photo-detectors, scintillators, or transistors).

The invention finds applications in the following fields:
Detection of X-ray radiation for medical applications, in particular for applications centred on mammography (detection of radiation centred around 18-20 keV, standard IEC 62220-1-2:2007), imager for conventional X-ray radiography (detection of radiation centred around 50 keV, RQA5 standard IEC 62220-1, or centred on 90 keV, RQA9 standard IEC 62220-1); in these two cases, the thickness of the ABX₃ layer is thick to absorb a significant portion of the radiation (typically from 0.1 mm to 2 mm),
Photovoltaic, or UV, visible or infrared photo-detector, with small thicknesses of the inorganic perovskite layer ABX₃ (typically from 100 nm-2 μm),
Detection of hard X-ray or gamma radiation with large thicknesses of inorganic perovskite ABX₃ (typically from 1 mm to 10 mm).

The method for manufacturing an inorganic perovskite layer 1 comprises the following steps:

a) providing a substrate 10 and an inorganic target 20,

b) positioning the substrate 10 and the target 20, in a close-space sublimation furnace,

c) depositing an inorganic perovskite layer 1 over the substrate 10 by sublimation of the target 20.

The method allows forming a perovskite material layer 1 (PVK) over a substrate 10. The thickness of the layer 1 can range from 100 nm to 10 mm depending on the targeted applications. The composition of the perovskite layer is homogeneous regardless of the thickness of the formed layer.

In general, this invention applies to any perovskite of general chemical formula ABX₃, including mixed compositions such as A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ with A⁽ⁿ⁾ and B⁽ⁿ⁾ cations and X⁽ⁿ⁾ anions, the compositions respecting electronic neutrality, with y₂ and yₙ the respective proportions of the cations A⁽²⁾ and A(ⁿ), z₂ and zₘ the respective proportions of the cations B⁽²⁾ and B^{(m)}, and x₂ and xₚ the respective proportions of the anions X⁽²⁾ and X₍ₚ₎.

According to a first variant:

A is selected from among Cs, Rb, K, Li, and Na,

B is selected from among Pb, Sn, Ge, Hg and Cd,

X is selected from among Cl, Br, I, and F.

Preferably, it is CsPbBr₃. For example, for mammography (energy ˜18 keV), a thickness of 200 μm of CsPbBr₃ allows absorbing 99.9% of the signal, and for general radiography (energy centred around 50 keV) a 700 μm layer of CsPbBr₃ allows absorbing similarly to 600 μm of CsI (indirect detection standard), which represents about 90% absorption.

According to a second variant, it is also possible to have alloys of 2 to 5 elements on one of the sites, on two of the sites or on the three sites A, B and X. For example, one could select a material with X═ClₖBrₗI₁₋ₖ₋ₗ with 0≤k, l≤1 and 0≤k+l≤1. The same applies for sites A and B.

According to a third variant, it is also possible to have double arrays with A=A′₂, B=C′¹+D′³+ and X₃=X′₆ namely a material of formula A′₂C¹+D³+X₆ with:

A′ selected from among Cs, Rb, K, Li, and Na,

X′ selected from among Cl, Br, I, and F

C′¹+ selected from among Ag, Au, Tl, Li, Na, K, and Rb,

and D³+ selected from among Al, Ga, In, Sb, and Bi.

Preferably, according to this variant, the perovskite material is of formula Cs₂AgBiBr₆.

The invention also applies to all other compositions similar to perovskites: materials of composition A₂B⁴⁺X₆ such as Cs₂Te⁴⁺I₆, materials of composition A₃B₂³⁺X₉, such as Cs₃Bi₂I₉, or other types of materials (Chalcogenides, Rudorffites . . . ).

In the case where the target 20 is of formula ABX₃, the target 20 can be formed from a mixture of elementary particles A, B and X.

According to other embodiments, the target 20 of formula ABX₃ can be formed:
of a mixture of binary particles AX and BX₂,
of a mixture of particles AX, BX₂ and ABX₃,
of particles ABX₃, which allows directly having the right composition and the right phase of the material to be sublimated; these particles could, for example, be small single crystals formed by a liquid process, by Bridgman or another solution.

It is also possible to use mixtures comprising more than two types of binary particles. For example, the compound Cs₂AgBiBr₆ can be obtained from precursors CsBr, AgBr, and BiBr₃.

In the case where the target 20 is of formula A′₂C¹⁺D³⁺X₆, the target may be composed:
of a mixture of binary particles A′X, C¹⁺X and D³⁺X₃,
of a mixture of particles A′X, C¹⁺X and D³⁺X₃ and A′₂C¹⁺D³⁺X₆,
of particles A′₂C¹⁺D³⁺X₆, which allows directly having the right composition and the right phase of the material to be sublimated.

Compositions that are more complex and/or involving a greater number of precursors can also be considered.

According to a particular embodiment, the target 20 forms a solid wafer (in other words the particles are agglomerated). Preferably, the target 20 is a 1 to 10 mm thick solid wafer. For example, it has a thickness of 3 mm.

According to a particular embodiment, the target 20 is manufactured from ABX₃ single crystals. The target can either be cut to the appropriate dimensions from a larger ABX₃ single crystal, or by assembling smaller single crystals (typically millimetric or centimetric in size). An additional cutting/polishing step may be necessary when assembling smaller single crystals to ensure that they are well joined and form a flat tiling. The single crystal(s) used for the manufacture of the target can be formed by a liquid process, by Bridgman or another solution.

According to another particular embodiment, the particles of the target 20 can form a bed of powders.

The characteristic size (or the particle size distribution) of the particles forming the target 20 ranges, for example, from 5 μm to 1,000 μm, and preferably from 20 μm to 100 μm.

According to a particular embodiment, the target 20 is formed of an inorganic perovskite film deposited over a substrate, preferably compatible with high temperatures, for example over a glass substrate. This film may consist of an ABX₃ type perovskite such as CsPbBr₃.

The film is continuous. The film is homogeneous.

The film of the target 20 can be obtained by CSS deposition from another target (called intermediate target) or by any other deposition method, such as by growth in solution or by evaporation.

Such a film can be used to form thin, intermediate or thick layers. The thickness of the film forming the target 20 is larger than or equal to the thickness of the layer 1 to be deposited. Preferably, the thickness of the film forming the target 20 is strictly larger than the thickness of the layer 1 to be deposited.

For example, a 0.5 mm film can be used to form a 0.4 mm thick inorganic perovskite layer 1.

Preferably, the thickness of the film of the target 20 is at least 10 times and even more preferably at least 100 times larger than the thickness of the layer 1 to be deposited. This embodiment is particularly advantageous for forming thin inorganic perovskite layers 1. Advantageously, the target 20 can be used for several depositions (for example for at least 3 depositions and preferably for more than 20 depositions).

For example, a 0.5 mm film can be used to form more than 100 200 nm thick inorganic perovskite layers 1.

The dimension of the target 20, formed of a bed of powder or of agglomerated particles, or else of a film, can range, for example, from 1 cm² to 1 m².

The dimension of the target 20 corresponds to the size of the deposit to be made. For example, for a 40×40 cm² deposit, a target of the same dimension is used.

The target 20 can be monolithic a set of elements arranged in such a way as to form a paving with the size of the substrate 10.

The substrate 10 over which the inorganic perovskite layer 1 is deposited can be made of glass, of polyimide, for example of Kapton®, or of silicon. The substrate can be a TFT detector array or a CMOS detector array. The nature of the substrate depends on the intended application and the temperatures used during the process.

In turn, the substrate 10 can be positioned over a support 11. For example, a TFT array over a polyimide support can be used.

According to an advantageous embodiment, the substrate 10 can be covered by an intermediate layer 12 (or sublayer).

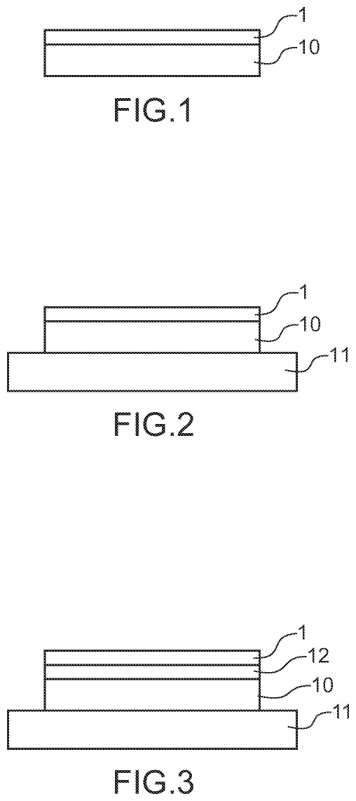

Upon completion of step c), it is therefore possible to obtain a stack comprising and preferably consisting of:
a substrate 10 and a perovskite layer 1 (FIG. 1),
a support 11, a substrate 10 and a perovskite layer 1 (FIG. 2),
a substrate 10, an intermediate layer 12 and a perovskite layer 1,
a support 11, a substrate 10, an intermediate layer 12 and a perovskite layer 1 (FIG. 3).

According to a first variant, the intermediate layer 12 is a layer of the same nature as the inorganic perovskite layer to be deposited, i.e. the intermediate layer 12 is a layer of formula ABX₃. This layer assists in the growth of the layer formed in step c). In particular, it can serve not only as a bonding layer, but also and above all as a crystallisation aid. The presence of the ABX₃ sublayer over the substrate enables homoepitaxy of the main layer.

According to a second variant, the intermediate layer 12 is made of ABX₃:D with D representing a doping element in the ABX₃ array. D can be an exogenous element placed in interstitial or substitutional, a gap in the ABX₃ array or any other doping mechanism. D can for example be Bi³⁺ or Sn⁴⁺ placed in substitution with respect to Pb²⁺. This doping allows obtaining a (p or n) doping sublayer different from the doping of the main layer (itself p, n or intrinsic doped). The role of this doped sublayer is to ensure better electrical contact with the rest of the device.

According to a third variant, the intermediate layer 12 is made of a perovskite consisting of a partially or totally different element. For example, a sublayer made of AB(X_{1-z}Y_{z})₃. An alloy (or a substitution of the elements) is possible on one, several ones or all of the sites A, B and X. It is also possible to consider a CH₃NH₃PbX₃ type organic-inorganic hybrid sublayer. The purpose of the sublayer is to exhibit different optoelectronic properties (gap energy, electron affinity, ionisation potential) in order to optimise the operation of the device.

According to a fourth variant, the intermediate layer 12 is of a completely different nature. It can be a crystalline layer or an amorphous layer. In this case, the intended role of the sublayer is to act as a buffer layer in order to compensate for the difference in coefficient of thermal expansion between the main layer and the substrate. This layer should be selected according to the substrate, its coefficient of thermal expansion and its ability to absorb stresses. For example, this sublayer could be:
a hybrid perovskite (organic-inorganic) of the Ruddlesden-Popper or Dion Jacobson type including a portion of organic nature which would allow relieving the residual mechanical stresses related to the differential CTEs,
a crosslinked or non-crosslinked polymer layer,
a mixture of polymer(s) and perovskite(s), or of small organic molecule(s) and perovskite(s),
a thin polycrystalline layer (<10 μm) of perovskite with or without a crosslinking agent to preserve cohesion between the grains via ionic or Wan der Waals forces (examples: 1,6-diaminohexane dihydrochloride (CAS: 6055-52-3)),
a layer or multi-layer comprising ductile materials, such as Zn, Pb, Al, Sn, . . .
a layer or multi-layer of any materials with intermediate CTEs between those of the PVK and of the substrate. The selection of materials depends on the substrate/deposited PVK pair,
a multi-layer having materials under compressive/tensile stress capable of compensating for the compressive/tensile stresses due to thermal expansion. The selection of materials depends on the substrate/deposited PVK pair.

The sublayer can be deposited continuously over the entire surface, or locally using direct deposition techniques (inkjet, screen-printing . . . ) or using lithography and photolithography techniques.

The intermediate layer 12 can serve one or more of the aforementioned roles/purposes. For example, an ABX₃:D layer deposited by evaporation can both serve as an electrical contact layer and enable the homoepitaxy of the main layer.

If the nature of the sublayer is different from the layer deposited during step c) but with a comparable mesh parameter, it can nevertheless promote the growth of this layer by heteroepitaxy.

The intermediate layer has a thickness smaller than the thickness of the layer deposited during step c). The thickness of the intermediate layer can range from a few tens of nanometres to a few microns.

An intermediate perovskite layer 12 can be deposited by CSS (with a different target), by vacuum evaporation, by a liquid process or any other method for depositing inorganic and organic/inorganic hybrid PVKs. As a non-limiting illustration, liquid process deposition can be carried out by spin coating, in solvent, by pulsed laser ablation (PLD “Pulsed Laser Deposition”) or by chemical bath deposition (CBD “Chemical Bath Deposition”).

Otherwise, the intermediate layer 12 can be deposited by vacuum thin layer deposition methods (evaporation, sputtering) or by deposition methods such as atomic layer deposition (ALD standing for “Atomic Layer Deposition”), electroplating, or growth in solution.

The intermediate layer 12 can also be deposited from the same target as that used for the main perovskite layer (step c). The composition of the target 20 then varies across its thickness (in other words, the target is formed of two different portions, each of the portions corresponding to a particular composition). The upper portion of the target consists of the constituent elements of the intermediate layer 12, the lower portion of the target consists of the constituent elements of the main layer 10. The upper portion of the target is thinner (0.1 μm-100 μm) than its lower portion (100 μm-10 mm). For example, this bilayer target can be manufactured by compacting different powders over an already compacted target, by ion implantation in a target or other methods.

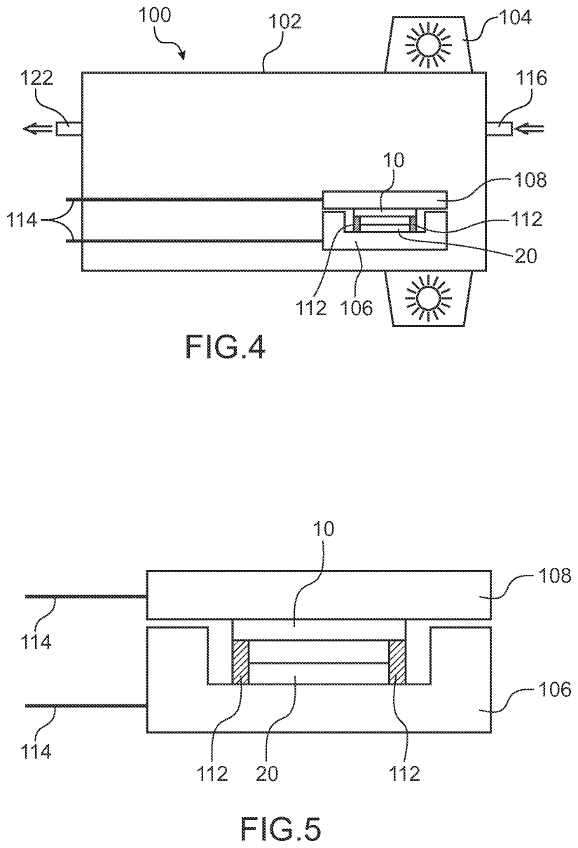

Step c) is carried out with a conventional CSS device 100 such as that one represented as a non-limiting illustration in FIGS. 4 and 5. However, it could consist of any other CSS device.

The CSS furnace 100 comprises a reactor 102 around which a heating system is positioned. For example, it may consist of lamps 104 (FIG. 4) or any other heating system (resistor for example).

The reactor 102 can be made of quartz, of graphite, of metal.

The reactor 102 can be tubular like in FIG. 1.

The furnace 100 also comprises a susceptor 106 (also called source block) and a cover 108 (also called substrate block). The susceptor 106 and the cover 108 are made of heat-conductive materials, which can withstand pressure, vacuum and high temperatures. Preferably, they are made of graphite.

The substrate 10 and the target 20 are positioned between the susceptor 106 and the cover 108.

Preferably, the substrate 10 is in direct contact with the cover 108 which keeps its temperature at the set value.

The PVK target 20 to be deposited is placed over the susceptor 106.

The substrate 10 is at a short distance from the target 20 (typically from 0.5 mm to 5 mm, for example 2 mm). A trade-off will be chosen between a distance sufficiently close to have a high deposition rate and a distance sufficient to be able to maximise and preserve the thermal gradient during the deposition.

One or more spacer(s) 112 made of a heat-insulating material (for example glass, quartz, or alumina) are used to keep the substrate 10 at a short distance from the target 20.

The cover 108 can be held pressed on the substrate by a closure system in the susceptor 106, not represented (for example a screw or any other fastening system).

Each of the susceptor 106 and the cover 108 has a thermocouple 114 or any other system (pyrometer, . . . ) to measure and control their temperature.

A heating system (lamp, resistors, . . . ) allows regulating the temperature of the susceptor 106 (T_{target}) and of the cover 108 (T_{substrate}) in a range that can vary from 20° C. to 600° C. Temperature rise ramps can be controlled in a range, for example, from 0.1° C./s to 10° C./s. The susceptor 106 (T_{target}) and the cover 108 (T_{substrate}) can be controlled by temperature ramps (or sequences of ramps), independently. Thus, it is possible to adjust the sublimation kinetics of the target and the condensation temperatures on the substrate so as to properly control the morphology of the layer according to the deposited thickness. In particular, these parameters can affect the size of the grains of the polycrystalline layer thus deposited over the substrate.

It is possible to add specific cooling devices for the cover 108 (for example, integrated liquid coolant piping, shields against radiation from the susceptor, radiators

The device 100 is connected to a system with an inert gas supply 116 (such as argon or N₂).

The device 100 can also be connected to an oxidising gas supply (such as O₂) or to a reducing gas supply (such as H₂).

The device 100 comprises a gas outlet 122, connected to a pumping system allowing reaching a vacuum Pfurnace ranging, for example, from 0.00001 Pa-1 Pa. The value Pfurnace depends on the used CSS furnace.

During step c), the target is sublimated. The deposition by sublimation is done by heating the susceptor 106 and the cover 108 under vacuum.

During step c), the temperature of the substrate T_{sub} is lower than the temperature of the target T_{target} in order to create a thermal gradient. During step c), the substrate is advantageously kept at a controlled temperature. The same applies for the target.

The temperature difference T_{target}−T_{sub} is from 20° C. to 350° C., preferably from 50° C. to 250° C. and even more preferably from 100° C. to 250° C., for example 150° C.

The targeted temperatures depend on the material to be deposited and are adjusted according to its phase diagram. For example, for the CsPbBr₃ material, it is possible to select T_{target}=400° C. (±100° C.) and T_{substrate}=250° C. (±100° C.).

For example, it is possible to perform temperature rise ramps comprised between 0.2° C./s and 10° C./s, for example of 1° C./s.

According to a first variant, the deposition step (sublimation) is performed at low pressure (typically lower than 1 Pa). Advantageously, the pressure during step c) ranges from 0.001 Pa to 1 Pa. For example, it is possible to select Pfurnace=0.01 Pa.

To carry out step c), it is possible to perform neutral gas pumping/purging cycles to evacuate oxygen from the device 100 and set it at low pressure.

According to other variants, to promote the growth of the grains (germination, nucleation then growth), it might be interesting to work during step c) under an oxidising atmosphere or under a reducing atmosphere.

The oxidising atmosphere can be obtained by setting a low partial pressure (preferably from 0.1 to 10 Pa, for example 1 Pa) in Ar:O₂ (1 at %<O₂<10 at %)) during this step.

The reducing atmosphere can be obtained by setting a low partial pressure (preferably 0.1 to 10 Pa, for example 1 Pa), in Ar:H₂ (1 at %<H₂<10 at %)) during this step.

The deposition time depends on the targeted thickness. For example, for medical X-ray detection applications, the targeted thicknesses are from 100 μm to 2 mm and deposition times from 15 min to 5 h will be selected.

After step c), the formed perovskite layer is cooled. Cooling can be natural or controlled by ramps. A rapid cooling system (by water or liquid coolant in pipes inserted in the susceptor and the cover) can also be considered.

According to a particular embodiment, the method comprises an additional step at high pressure, between step b) and step c).

By high pressure, it should be understood a pressure higher than 10³ Pa, for example in the range of 10⁵ Pa. This step is particularly advantageous in the case of the use of a target 20 comprising a mixture of powders, for example a mixture of AX and BX₂ powders. Indeed, this high-pressure step allows obtaining the ABX₃ phase (thanks to the AX+BX₂→ABX₃ reaction) before the sublimation of the target 20 and therefore sublimating only the right crystallographic phase. Hence, a very good quality deposit is obtained. This variant is also particularly interesting in the case of a target 20 formed of a bed of powder since it allows agglomerating the particles and/or compacting the target.

The method may also comprise, before step a), a step during which the target 20 of formula ABX₃ is manufactured.

The manufacture of the target requires shaping particles so as to form a target.

The particles can be obtained by grinding or by co-grinding.

Shaping can be achieved by pressing the particles so as to obtain a solid target.

According to a first variant, the particles forming the target are obtained by grinding a material of formula ABX₃. The grinding step allows adjusting the size of the particles.

According to a second variant, the particles forming the target are obtained by co-grinding a first material of formula AX and a second material of formula BX₂.

According to a third variant, the particles forming the target can be obtained by co-grinding of three materials A, B and X.

The relative amounts of the different materials will be selected so as to form a target of formula ABX₃.

The grinding or co-grinding step can be carried out in a planetary ball mill.

Preferably, the particles forming the target 20 are obtained by mechanosynthesis. Mechanosynthesis consists in carrying out a very energetic co-grinding of pure or pre-alloyed materials in a high-energy mill, until a powder is obtained whose particles are single-phase or polyphase. For example, the mixture of AX and BX₂ can lead to obtaining single-phase particles (ABX₃) or an ABX₃+AX+BX₂ mixture.

An energetic grinding is induced for example by:
a large mass of balls compared to the mass of powder (at least 2 times larger, for example 15 times larger), and/or
a high rotational speed (typically from 50 revolutions/min at 700 revolutions/min, for example 300 revolutions/min), which depends on the used mill as well as the mass of balls and powders, and/or
a long grinding time (between 1 h and 10 h, for example 5 h).

According to another embodiment, the particles are not co-ground before shaping the target. For example, when the powder comprises a mixture of different particles, for example AX and BX₂, it is possible to eliminate the co-grinding phase. In this case, the formation of ABX₃ can be done:
either in the target before sublimation (in the CSS furnace) during the high-pressure step following the AX+BX₂→ABX₃ reaction
or directly over the substrate following the AX+BX₂→ABX₃ reaction after separate sublimation of AX and BX₂; In this case, the amounts of AX and BX₂ should be adjusted according to their sublimation temperature in order to preserve the final ABX₃ composition in the deposit. In a particular case of the invention, the composition of the target is not stoichiometric, but the deposition conditions and the relative rates of deposition of the different precursors lead to a stoichiometric layer on the substrate over which the deposition is done.

The advantage of this variant is to eliminate the grinding step, thus leading to time and cost savings.

According to a particular embodiment, the powder of formula ABX₃ is pressed to form a solid wafer (or target). In other words, the particles are agglomerated.

A manual press can be used. The pressure to be applied is comprised between 10⁵ Pa·cm⁻² and 10⁸ Pa·cm⁻², for example 10⁷ Pa·cm⁻².

As a variant of the manual press, it is possible to press while heating (for example at T=250° C.±200° C.) to improve the compactness of the target and promote the formation of ABX₃ in the target.

In particular, pressing while heating can be done by flash sintering (or SPS for “Spark Plasma Sintering”) which allows for a good compactness while preserving a fine particle size distribution (more homogeneous target).

According to another particular embodiment, the pressing step is not necessary if it is desired to use a bed of powders for the CSS process. In this case, the necessary amount of powder (an AX/BX₂ or ABX₃ mixture) is disposed directly over the susceptor 106 or over a support positioned over the susceptor 106. In the case of the AX/BX₂ mixture, it might be necessary to adjust the amounts of AX and BX₂ according to their sublimation temperature in order to preserve the final ABX₃ composition in the deposit.

The elimination of the pressing step saves time and costs.

The powder mass to be used to form the target depends on the size and the thickness of the desired target, for example 4 to 5 g·cm⁻³ will be used.

Preferably, powder handling is done in a glove box under an inert atmosphere (Ar or N₂) with a low O₂ and H₂O content.

### Illustrative and Non-Limiting Embodiments

### Method for Manufacturing a Thick Layer of CsPbBr₃₋

In this example, a 3 mm thick CsPbBr₃ target for a surface of 40×40 cm² is manufactured at first.

The target is manufactured from AX particles and BX₂ particles with A=Cs, B=Pb and X=Br.

The AX powders and the BX₂ powders are commercially available. They have a purity higher than 99% (from 99% to 99.999%). Each of these powders is white.

Opening of the powder containers and handling of the powder is done in a glove box under an inert atmosphere (Ar or N₂) with a low O₂ and H₂O content.

A defined mass of each powder is stoichiometrically collected so that the final composition of the mixture is ABX₃. Consider m_{T} the targeted mass of the ABX₃ target. Hence, the respective masses of AX (m_{AX}) and BX₂ (m_{B}) to be collected are:

m_{AX}=m_{T}×(M_{A}+M_{X})/M_{A}+M_{B}+3M_{X})

m_{BX2}=m_{T}×(M_{B}+2M_{X})/(M_{A}+M_{B}+3M_{X})

with M_{A}, M_{B}, and M_{X} are the molar masses of the elements A, B and X respectively.

To prepare a 10 g target of CsPbBr₃, 3.67 g of CsBr and 6.33 g of PbBr₂ should be collected.

The two powders are placed in a grinding bowl (made of stainless steel, tungsten carbide or other) with a mass of grinding balls mbilles 15 times greater than the total mass m_{T} of powder. The selection of the bowl size is controlled by the amount of powder: for example, the bowl will be selected so that all of the balls and powder fill about ⅓ of the bowl. The bowl is hermetically sealed to be placed in a planetary mill.

The rotational speed v_{R} is high (˜300 revolutions per minute) and the grinding time is about 5 hours.

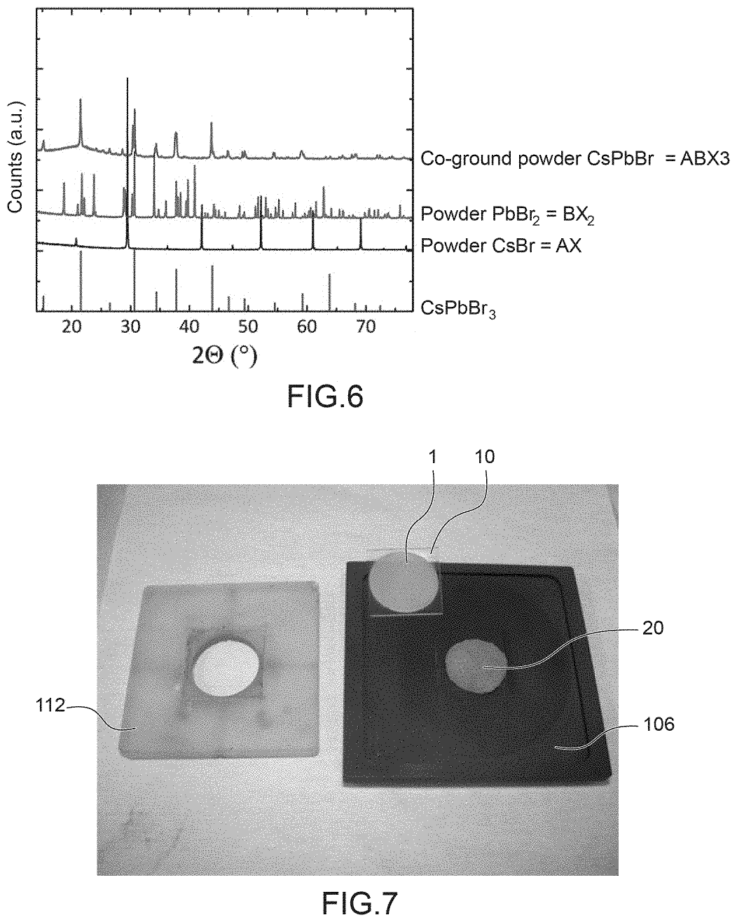

The colour change of the powder from white to orange is an indication of the formation of the ABX₃ phase. Characterisations by X-ray powder diffraction allow in a second step performing a qualitative and quantitative analysis of the obtained composition. The peaks of the co-ground powder (target) correspond to those expected for the CsPbBr₃ phase, confirming that the target is actually in the expected crystallographic phase (FIG. 6).

Afterwards, the powder thus obtained is pressed to form a solid wafer. A manual press can be used. The order of magnitude of the pressure to be applied is 107 Pa·cm⁻². The used powder mass is about 4.5 g·cm⁻³.

Afterwards, the deposition of the thick layer of ABX₃ is done in a conventional CSS furnace.

Furnace Ar pumping/purging cycles are performed to evacuate oxygen then the furnace is set at low pressure (0.1 Pa).

The deposition by sublimation is done by heating the susceptor 106 and the cover 108, with T_{target}=400° C. (±100° C.) and T_{substrate}=250° C. (±100° C.). The temperature of the substrate 10 is lower than the temperature of the target 10 by 150° C.

The temperature rise ramps are 1° C./s.

A circular target and a spacer having a through hole of the same dimension as the target are used.

FIG. 7 represents the deposit obtained over a glass substrate. The deposit has the shape of the target and of the through hole of the spacer.

The deposition time depends on the targeted thickness. For medical X-ray detection applications, the targeted thicknesses are from 100 μm to 2 mm. Consequently, deposition times from 15 min to 5 h will be selected.

If a high pressure step is added, before step c), it is possible to carry out the following cycle:
high pressure step: T_{target}˜300° C., T_{substrate}˜150° C., P_{furnace}=10⁵ Pa in Ar (>10³ Pa), duration 30 min,
step c): T_{target}˜400° C., T_{substrate}˜250° C., P_{furnace}=0.1 Pa in Ar (<10 Pa), duration 2 h.

### Method for Manufacturing an X-Ray Detector for Mammography:

Typically, the detectors used for mammography are 20×24 cm² and are optimised to detect the radiation at 18-20 keV (standard IEC 62220-1-2:2007).

For this application, it is possible to consider a flexible substrate, for example a TFT array deposited over a polyimide support.

The manufacturing method comprises the following steps:
Providing a TFT array on polyimide; array pixel step of the TFT array: 75 μm.
Depositing one (or a superposition of) layer(s) capable of blocking electrons (for example NiOx or AIOx) by ALD (“Atomic Layer Deposition”) or by any other method such as by evaporation, sputtering, or by liquid process deposition; as example, a polymer, such as PTAA or Poly[bis(4-phenyl) (2,4,6-trimethylphenyl)amine), can be deposited by spin coating, or a molecule, for example Spiro-OMeTAD (CAS: 207739-72-8) by vacuum evaporation.
Manufacturing 16 0.7 mm thick CsPbBr₃ targets with a surface area of 5×6 cm² by mixing 57 g of CsBr and 98 g of PbBr₂ in a grinding bowl with 600 g of steel balls for 5 hours at 300 rpm then successively pressing the 16 targets in an automatic press with a pressure of 3×10⁸ Pa.
Positioning the 16 targets in a 20×24 cm² graphite furnace at 2 mm from the substrate.
Depositing a 500 μm thick layer of CsPbBr₃ by CSS with the following conditions: 400° C. (target)/225° C. (substrate) for 1h30 at P=0.01 Pa.
Depositing one (or a superposition of) hole-blocking layer(s) (TiO₂:Mg, Nb₂O₅, CdS, C60, 60PCBM, SnO₂, ZnO . . . ) and an upper electrode (for example made of metal, transparent conductive oxide, . . . ).

### Method for Manufacturing an Imager for X-Ray Radiography (Hand, Thorax, Joint, Fracture, . . . ):

The imagers for X-ray radiography have a dimension of 42×42 cm² and the used radiation is centred around 50 keV (RQA5 standard IEC 62220-1).

The method comprises the following successive steps:
Providing a rigid (glass) or flexible (polyimide) support over which is deposited a TFT array (pixel step 180 μm) as well as one (or a superposition of) hole-blocking layer(s) (TiO₂:Mg, Nb₂O₅, CdS, SnO₂, C60, 60PCBM . . . ).
Preparing 36 square targets of 1 mm thickness, 7×7 cm² (i.e. about 800 g of powder: 300 g CsBr, 515 g PbBr₂). Co-grinding of the powders with a mass of balls 10 times greater for 5 h at 300 revolutions/min.
Positioning the targets and the support/substrate stack in the CSS furnace, a spacer holding the substrate 2 mm away from the targets.
Depositing an active layer of 0.8 mm of CsPbBr₃ with the following conditions: 400° C. (target)/225° C. (substrate) for 2 h at P=0.01 Pa.
Depositing one (or a superposition of) electron-blocking layer(s) and an upper electrode (for example made of metal, conductive transparent oxide, . . . ).

### Method for Manufacturing an Imager for Real-Time X-Ray Imaging—Placement of an Arterial Endoprosthesis (Cardiac “Stent”) for Example:

The imagers for real-time X-ray imaging have reduced dimensions (21×21 cm²) but the used radiation is more energetic (RQA9, standard IEC 62220-1). The architecture of the detector is similar (while reducing the dimensions of the targets and of the furnace to adapt to the targeted size), the thickness of the CsPbBr₃ layer is about 1.2 mm. Hence, the thickness of the targets is 1.5 mm and the deposition time about 2h30.

### Method for Manufacturing an Inorganic PVK Based Photovoltaic Module:

The targeted thicknesses of the materials, relatively small (between 100 nm and 2 μm), require shorter deposition times. The deposit being finer, it can be obtained from a bed of powders. Moreover, the surface of the substrate (and therefore of the entirety of the furnace and susceptor is larger): typically 60 cm×120 cm. For example (non-restrictive example), it is possible to consider CsPb(I_{0.66}Br_{0.33})₃ as an absorber material. The method only describes the deposition of the different layers; the portion placed into standard module by P1-P3-P3 interconnection for example is not described

The method is performed as follows:
Providing a support made of glass+FTO (fluorine-doped tin oxide) over which is deposited an electron transport layer (TiO₂ type deposited by liquid process, ALD or other),
Manufacturing the target by mixing 2 powders of CsBr and PbI₂ in order to obtain a powder comprising CsBr and PbI₂ intimately mixed and homogeneous, then by uniformly distributing the CsBr/PbI₂ powder over the susceptor (provide for about 1 g/cm² of powder),
Depositing the CsPb(I_{0.66}Br_{0.34})₃ layer with CSS deposition in 2 steps:

at first: T_{target}˜250° C. (±50° C.), T_{substrate}˜100° C. (±50° C.), P_{furnace}=10⁵ Pa in Ar, duration 10 min to obtain the CsBr+PbI₂->CsPb(I_{0.66}Br_{0.33})₃ reaction in the target

then T_{target}˜350° C. (±50° C.), T_{substrate}˜200° C. (±50° C.), P_{furnace}=0.1 Pa in Ar (<10 Pa), duration 10 min; sublimation of 500 nm of CsPb(I_{0.66}Br_{0.33})₃
Depositing a hole-transporting layer (for example of the Spiro-OMeTAD type (CAS: 207739-72-8) or PTAA (Poly[bis(4-phenyl) (2,4,6-trimethylphenyl)amine)),
Depositing the rear electrode (for example made of Au or Ag).

Alternatively, this method can be performed on a first crystalline Si solar cell (instead of the glass/OTF support) to make a Si/PVK tandem cell. For the tandem application, it is possible to deposit a layer of CsPb(Cl_{0.34}Br_{0.66})₃ instead of CsPb(I_{0.66}Br_{0.33})₃ using CsCl and PbBr₂ powders to have a higher band gap energy. It will also be necessary to insert a tunnel junction beneath the FTO layer and to replace the rear electrode with a transparent and conductive electrode (transparent conductive oxide type, carpet of silver nanowires, . . . ).

### Method for Manufacturing an Inorganic PVK Based Near-Infrared Imager:

The targeted thicknesses of the materials, relatively small (between 100 nm and 2 μm), require shorter deposition times. The deposit being finer, it can be obtained from a bed of powders. For example (non-restrictive example), it is possible to consider CsSnI₃ as an absorber material. The method only describes the deposition of the different layers.

The near-infrared imager has dimensions of 5×5 cm² and absorbs up to 940 nm.

The method for manufacturing the imager comprises the following successive steps:
Providing a rigid (glass) or flexible (polyimide) support over which is deposited a TFT array (pixel step 180 μm) as well as a layer or superposition of hole-blocking layer(s) (TiO₂:Mg, Nb₂O₅, CdS, SnO₂, C60, 60PCBM . . . ).
Preparing a 1 mm thick square target of 5×5 cm² by co-grinding the powders with a mass of balls 10 times greater for 5 hours at 300 revolutions/min.
Positioning the targets and the support/substrate stack in the CSS furnace, a spacer holding the substrate 2 mm away from the targets.
Depositing a 300 nm active layer of CsSnI₃ with the following conditions: 400° C. (target)/225° C. (substrate) for 2 h at P=0.01 Pa.
Depositing a layer or a superposition of electron-blocking layer(s) (PTAA) and a semi-transparent upper electrode (for example made of a conductive transparent oxide, . . . ).
   Method for Manufacturing a Scintillator to Detect Gamma Radiation for Medical Applications (Example of Scintigraphy, Radiation at 140 keV):

Scintillators are devices for the indirect detection of radiation: this is transformed into visible light which, in turn, is captured by a photo-detector. The use of a scintillator can be done for the detection of X-rays (10²-10⁵ eV) or gamma rays (>10⁵ eV). We will give here an example of a scintillator for gamma detection, but the principle is the same for X-ray detection.

Gamma radiation detectors are useful in many fields: medical (tomography) but also the industrial field (non-destructive inspection, security system), the geophysical field (nature analysis of the ground for oil exploration), the public security field (luggage control, vehicles), the fundamental research field.

We will more particularly describe the method for manufacturing a scintillator to detect gamma radiation for medical applications (example of scintigraphy, radiation at 140 keV). The imagers measure 40×40 cm².

The method comprises the following steps:
Providing a TFT array on a rigid support (glass) over which is deposited an organic or amorphous silicon photo-detector array.
Depositing a 2 mm thick layer of CsPbBr₃ by CSS. The same deposition method is used for the 2.5 mm thick X-ray detector for mammography (tiling of 25 targets of 6×6 cm²).

The deposition time is comprised between 3 h and 4 h.
Depositing a protective aluminium layer by sputtering.

### REFERENCES

[1] Stoumpos, C. C., et al., Crystal growth of the perovskite semiconductor CsPbBr3: a new material for high-energy radiation detection. Crystal growth & design, 2013. 13(7): p. 2722-2727.
[2] Yakunin, S., et al., Detection of gamma photons using solution-grown single crystals of hybrid lead halide perovskites. Nature Photonics, 2016. 10(9): p. 585.
[3] Pan, W., et al., Hot-Pressed CsPbBr3 Quasi-Monocrystalline Film for Sensitive Direct X-ray Detection. Advanced Materials, 2019. 31(44): p. 1904405.
[4] WO 2017/031193 A1

What is claimed is:

1.-17. (canceled)

18. A method for depositing an inorganic perovskite layer onto a substrate comprising the following steps:
a) providing a substrate and an inorganic target,
b) positioning the substrate and the target, in a close-space sublimation furnace (100),
c) depositing an inorganic perovskite onto the substrate by sublimation of the target.

19. The method according to claim 18, wherein the inorganic perovskite layer has the formula A′₂C¹⁺D³⁺X₆, A₂B⁴⁺X₆ or A₃B₂³⁺X₉ with A, A′, C, D and B being cations and X being an anion.

20. The method according to claim 18, wherein the inorganic perovskite layer has the formula A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ with A and B being cations and X being anions.

21. The method according to claim 18, wherein the inorganic perovskite layer has the formula ABX₃ with A and B being cations and X being an anion.

22. The method according to claim 21, wherein the inorganic perovskite layer is made of CsPbBr₃.

23. The method according to claim 22, wherein the inorganic perovskite layer has a thickness larger than or equal to 100 μm.

24. The method according to claim 21, wherein the target comprises particles of formula ABX₃.

25. The method according to claim 21, wherein the target comprises particles of formula AX and particles of formula BX₂.

26. The method according to claim 21, wherein the target comprises particles of formula AX, particles of formula BX₂ and particles of formula ABX₃.

27. The method according to claim 24, wherein the target provided in step a) is obtained according to the following steps:
mechanosynthesis by co-grinding of a first material of formula AX and a second material of formula BX₂ so as to obtain a powder of formula ABX₃,
pressing the powder of formula ABX₃ to obtain a solid target of formula ABX₃.

28. The method according to claim 24, wherein, before step c), the method comprises an additional step during which the target is heated up to temperatures from 100° C. to 500° C. and is subjected to a pressure higher than 10³ Pa.

29. The method according to claim 18, wherein the target is formed of an inorganic perovskite film.

30. The method according to claim 18, wherein, during step c), the temperature difference between the target and the substrate ranges from 50° C. to 350° C.

31. The method according to claim 18, wherein, during step c), the temperature difference between the target and the substrate ranges from 50° C. to 200° C.

32. The method according to claim 18, wherein step c) is carried out at a pressure P lower than 1 Pa.

33. The method according to claim 18, wherein step c) is carried out at a pressure P lower than 0.1 Pa.

34. The method according to claim 18, wherein step c) is carried out under a reducing atmosphere or under an oxidising atmosphere.

35. The method according to claim 18, wherein, before step c), the method comprises a step during which an intermediate layer, of a nature identical to or different from the inorganic perovskite layer, is deposited onto the substrate.

36. A stack comprising a substrate and an inorganic perovskite layer obtained by the method according to claim 18, the inorganic perovskite layer being made of CsPbBr₃ and having a thickness larger than or equal to 100 μm.

37. A use of a stack as defined in claim 36, for X detection applications.
